(19) United States
(12) Patent Application Publication
(10) Pub. No.: US 2011/0278669 A1
(43) Pub. Date: Nov. 17, 2011

(54) SEMICONDUCTOR DEVICE

(75) Inventors: Tomoyuki MIYOSHI, Akishima (JP); Shinichiro Wada, Fuchu (JP); Takayuki Oshima, Ome (JP); Yohei Yanagida, Hamura (JP); Takahiro Fujita, Fussa (JP)

(73) Assignee: HITACHI, LTD.

(21) Appl. No.: 13/105,145

(22) Filed: May 11, 2011

(30) Foreign Application Priority Data
May 11, 2010 (JP) 2010-108904

(51) Int. Cl. H01L 29/78

(52) U.S. Cl. 257/335; 257/356; 257/E29.256

(57) ABSTRACT

Disclosed is a high-voltage diode structure which realizes high reverse recovery capability and high maximum allowable forward current. The distance between a longitudinal end of a p well layer in an anode region and an element isolation region formed to surround the diode is 5 μm or shorter so as to allow a depletion layer to reach the element isolation region when a maximum rated reverse voltage is applied. During reverse recovery, the electric field strength at an end portion of a p well layer is reduced, hole current is reduced, and local temperature rises are reduced.

### CLAIM OF PRIORITY

The present application claims priority from Japanese patent application JP 2010-108904 filed on May 11, 2010, the content of which is hereby incorporated by reference into this application.

### FIELD OF THE INVENTION

The present invention relates to element structures of a high-voltage diode and a high-voltage metal-oxide semiconductor (MOS) having high reverse recovery capability.

### BACKGROUND OF THE INVENTION

P-n junction diodes which allow current to flow only unidirectionally are among high-voltage elements. FIG. 1 shows a circuit diagram of a boosting DC/DC converter as an example of a semiconductor IC device including a diode. The circuit is for providing an output voltage Vout higher than an input voltage Vi by accumulating energy in an inductor 4 when a switching element 2 (configured, in many cases, by a MOSFET) is on and adding the accumulated energy to the input power supply when the switching element 2 is off. The voltage gain can be calculated as (1+T1/T2) where T1 is the on time of the switching element 2 and T2 is the off time of the switching element 2. In the circuit, a diode 1 serves to cause current to flow to a capacitor 5 when the switching element 2 is off and hold charges in the capacitor 5 when the switching element 2 is on. Hence, the diode 1 is required to have good forward current performance and high voltage resistance.

Abruptly applying a reverse voltage to the diode 1 in a state where a forward current is flowing therethrough causes a reverse current to flow through the diode 1 for a while. This is because the abrupt application of the reverse voltage causes the minority carriers stored in the diode by carrier conductivity modulation to be discharged backward with high energy. The reverse current thus caused is referred to as “reverse recovery current.” When the reverse recovery current exceeds a certain threshold value, the diode is broken by heat generated by the excessive current. Hence, the forward current that may be made to flow through a diode is limited. A maximum allowable forward current value for a diode is generally referred to as the “reverse recovery capability” of the diode.

A high-voltage diode structure described in Japanese Unexamined Patent Publication No. 2003-224133 is aimed at enhancing the performance of an ESD protection diode. In the structure, an anode region and a cathode region selectively formed on a semiconductor surface include an anode and a cathode having different lengths so as to reduce current concentration, particularly, reverse avalanche current concentration. When an anode and a cathode having a same length are arranged side by side, current concentrates more at mutually corresponding longitudinal ends of the anode and cathode than at mutually facing long sides of the anode and cathode. This is because current flowing on the outer side of a longitudinal end of the anode or cathode can flow to the inner side along the periphery of the longitudinal end. Hence, the longitudinal ends of the anode and cathode easily break down. According to Japanese Unexamined Patent Publication No. 2003-224133, current concentration at the longitudinal ends of the anode and cathode at a time of a reverse avalanche can be reduced by forming the anode and cathode in different lengths so as not to allow their longitudinal ends to easily break down.

### SUMMARY OF THE INVENTION

The reverse recovery capability of a diode is not mentioned in Japanese Unexamined Patent Publication No. 2003-224133. The inventors of the present invention have noticed that the reverse recovery capability of a diode is affected by distance d between the p well layer forming an anode region and the element isolation region. FIGS. 2A to 2C are a plan view, a sectional view (A-A′), and another sectional view (B-B′), respectively, of an example of a diode. In an anode region 18, a p well layer 8 is selectively formed on an n⁻ drift layer 11, a p contact layer 13 is formed on the surface of the p well layer 8, and an anode 16 is conductively connected to the p contact layer 13 via an anode plug 14. In a cathode region 19, an n contact layer 9 is selectively formed on the n⁻ drift layer 11 and a cathode 17 is conductively connected to the n contact layer 9 via a cathode plug 15. As shown in FIG. 2A, the anode region 18 and the cathode region 19 are each stripe-shaped with their long sides opposed to each other, and the diode is surrounded by an element isolation region 10. The n⁻ drift layer 11 is, though not shown, formed on a buried oxide (BOX) layer formed over a silicon support substrate, and the element isolation region 10 is formed to reach the BOX layer.

Concerning the high-voltage diode shown in FIGS. 2A to 2C with distance d between a longitudinal end of the p well layer 8 in the anode region and the element isolation region 10 surrounding the diode assumed, in the present case, to be large (i.e. d=10 μm), FIGS. 3 to 6 show a depletion layer region (FIG. 3), equipotential lines (FIG. 4), flow of holes (FIG. 5), and isothermal lines (FIG. 6) calculated for a state with reverse recovery taking place. For the calculations, the n⁻ drift layer 11 was diffused with phosphorus at a dose of 2E15 cm⁻² in a p-type semiconductor substrate doped with boron at a dose of 6.0E13 cm⁻²; the p well layer 8 was diffused with boron at a dose of 1E16 cm⁻²; the p contact layer 13 was diffused with boron at a dose of 1E16 cm⁻². The n contact layer 9 was diffused with phosphorus at a dose of 1E19 cm⁻². The p well layer 8 and the n contact layer 9 were arranged to be 12 μm apart. To evaluate reverse recovery, with the anode and peripheral electrodes kept at 0 V, a voltage of −3 V was applied to the cathode causing a forward current to flow, and the cathode voltage was raised to 100 V in 100 ns. Note that the X- and Y-directions in FIG. 3 correspond to directions A-A′ and B-B′ in FIG. 2A. FIGS. 7 to 10 and FIGS. 14 to 17 similarly correspond to FIG. 2A.

As shown in FIG. 5, holes flow toward a longitudinal end of the p well layer 8. Also, as shown in FIG. 3, a depletion region extends from between the p well layer 8 and n⁻ drift layer 11 into the n⁻ drift layer, but the portion between the longitudinal end of the p well layer 8 and the element isolation region 10 of the n⁻ drift layer 11 is not entirely depleted. Therefore, as shown in, FIG. 4, the potential gradient from the longitudinal end of the p well layer 8 toward the element isolation region 10 is steep increasing the electric field strength there. This causes current concentration at the longitudinal end of the p well layer 8 and, as shown in FIG. 5, concentrated heat generation there. Hence, that portion of the diode is considered to easily break down.

As described above, to enhance the reverse recovery capability of a diode, it is necessary to reduce the concentration of reverse recovery current in the diode. An object of the present invention is to provide a diode structure in which current concentration at a longitudinal end of a diffusion region in an anode region is reduced, enhancing the reverse recovery capability of the diode.

A diode according to an aspect of the present invention includes: a semiconductor layer of a first conductivity type; a first semiconductor region of a second conductivity type and a second semiconductor region both formed in the semiconductor layer, the second semiconductor region having a higher density than the semiconductor layer; and an element isolation region electrically isolating the semiconductor layer from a peripheral region. In the diode: the first semiconductor region and the second semiconductor region are each stripe-shaped and are arranged such that a long side of the first semiconductor region and a long side of the second semiconductor region oppose each other; and a distance between a longitudinal end of the first semiconductor region and the element isolation region is such that, when a maximum rated reverse voltage is applied, a depletion layer extending from the longitudinal end of the first semiconductor region at least contacts the element isolation region. The distance is preferably 5 μm or shorter.

According to the present invention, the reverse recovery capability of a high-voltage diode or a parasitic diode in a high-voltage transistor can be improved and the element size can be reduced.

### BRIEF DESCRIPTION OF THE DRAWINGS

FIG. 1 is a circuit diagram of a boosting DC/DC converter;

FIGS. 2A, to 2C show a diode structure with FIG. 2A being a plan view, FIG. 2B being a sectional view (A-A′), and FIG. 2C being another sectional view (B-B′);

FIG. 3 shows a depletion layer during reverse recovery in a diode with distance d being large;

FIG. 4 shows potential distribution during reverse recovery in a diode with distance d being large;

FIG. 5 shows the flow of holes during reverse recovery in a diode with distance d being large;

FIG. 6 shows temperature distribution during reverse recovery in a diode with distance d being large;

FIG. 7 shows a depletion layer during reverse recovery in a diode with distance d being 5 μm or shorter;

FIG. 8 shows potential distribution during reverse recovery in a diode with distance d being 5 μm or shorter;

FIG. 9 shows the flow of holes during reverse recovery in a diode with distance d being 5 μm or shorter;

FIG. 10 shows temperature distribution during reverse recovery in a diode with distance d being 5 μm or shorter;

FIG. 11 shows a circuit diagram of an evaluation circuit for measuring the reverse recovery capability of a diode;

FIG. 12 shows results of measuring the effect of the diode structure according to a first embodiment of the invention;

FIGS. 13A to 13C show a diode structure with FIG. 13A being a plan view, FIG. 13B being a sectional view (A-A′), and FIG. 13C being another sectional view (B-B′);

FIG. 14 shows a depletion layer during reverse recovery in the diode shown in FIGS. 13A to 13C;

FIG. 15 shows potential distribution during reverse recovery in the diode shown in FIGS. 13A to 13C;

FIG. 16 shows the flow of holes during reverse recovery in the diode shown in FIGS. 13A to 13C;

FIG. 17 shows temperature distribution during reverse recovery in the diode shown in FIGS. 13A to 13C;

FIGS. 18A to 18C show a diode structure with FIG. 18A being a plan view, FIG. 18B being a sectional view (A-A′), and FIG. 18C being another sectional view (B-B′);

FIG. 19A is a sectional view showing potential distribution during reverse recovery in the diode according to the first embodiment; and FIG. 19B is a sectional view showing potential distribution during reverse recovery in the diode according to a third embodiment;

FIG. 20 is a plan view of a diode structure;

FIGS. 21A to 21C show a high-voltage NMOS structure with FIG. 21A being a plan view, FIG. 21B being a sectional view (A-A′), and FIG. 21C being another sectional view (B-B′);

FIGS. 22A and 22B show a high-voltage NMOS structure with FIG. 22A being a plan view and FIG. 22B being a sectional view (B-B′); and

FIGS. 23A and 23B show a diode structure with FIG. 23A being a plan view and FIG. 23B being a sectional view (A-A′).

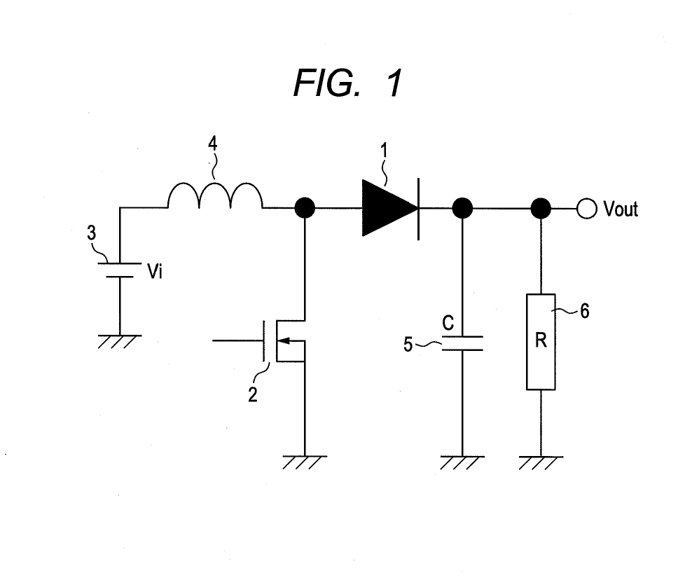

### DETAILED DESCRIPTION OF THE PREFERRED EMBODIMENTS

The conductivity types referred to in the following description are mere examples, and reversing the conductivity types used in the following embodiments does not affect the effects of the present invention.

### First Embodiment

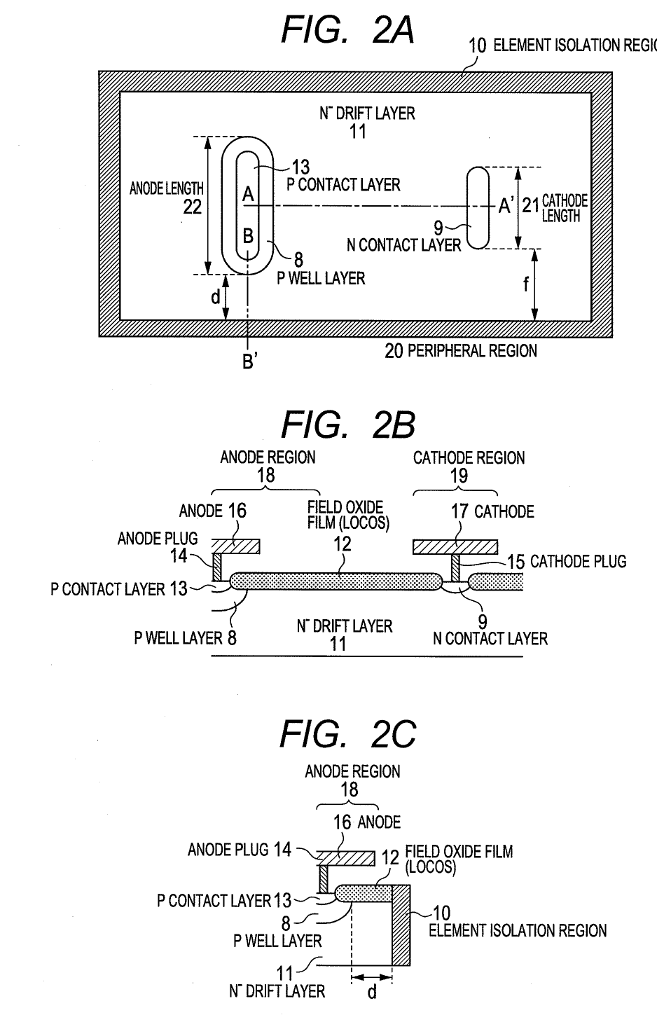

FIGS. 2A to 2C show a high-voltage diode according to a first embodiment of the present invention. In an anode region 18, a p well layer 8 is selectively formed on an n⁻ drift layer 11, a p contact layer 13 is formed on the surface of the p well layer 8, and an anode 16 is conductively connected to the p contact layer 13 via an anode plug 14. In a cathode region 19, an n contact layer 9 is selectively formed on the n⁻ drift layer 11 and a cathode 17 is conductively connected to the n contact layer 9 via a cathode plug 15. As shown in FIG. 2A, the anode region 18 and the cathode region 19 are each stripe-shaped with their long sides opposed to each other, and the diode is surrounded by an element isolation region 10. The layer 11 is, though not shown, formed on a buried oxide (BOX) layer formed over a silicon support substrate, and the element isolation region 10 is formed to reach the BOX layer. Distance d between a longitudinal end of the p well layer 8 in the anode region and the element isolation region 10 surrounding the diode does not exceed a predetermined distance, i.e. 5 μm in the present embodiment. Also, distance d does not exceed a distance over which a depletion layer formed, when a maximum rated reverse voltage V_{R} is applied, near the p well layer in the anode region extends. Namely, the depletion layer formed when a maximum rated reverse voltage V_{R} is applied contacts the element isolation region 10.

As for distance f between a longitudinal end of the cathode region and the element isolation region, when it is larger, the withstand voltage of the diode is larger. Hence, distance f is preferably larger than distance d.

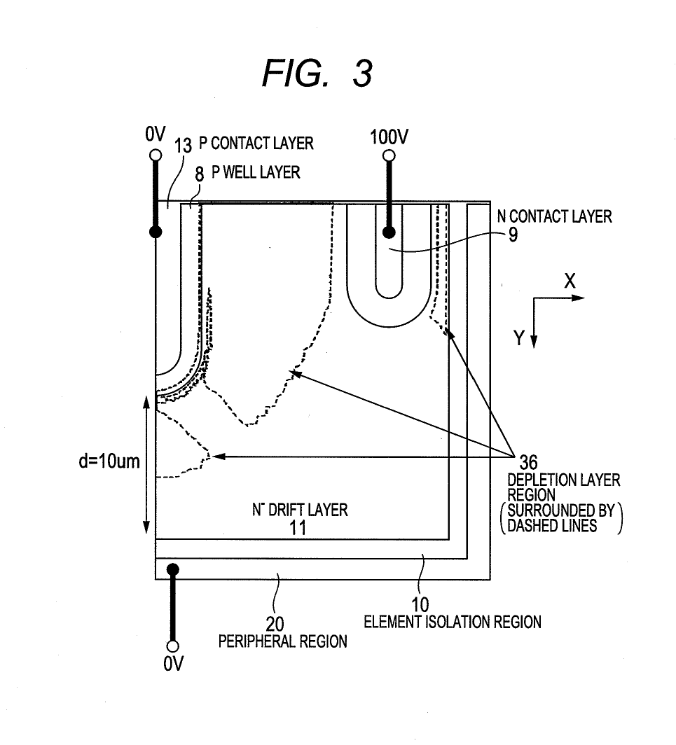

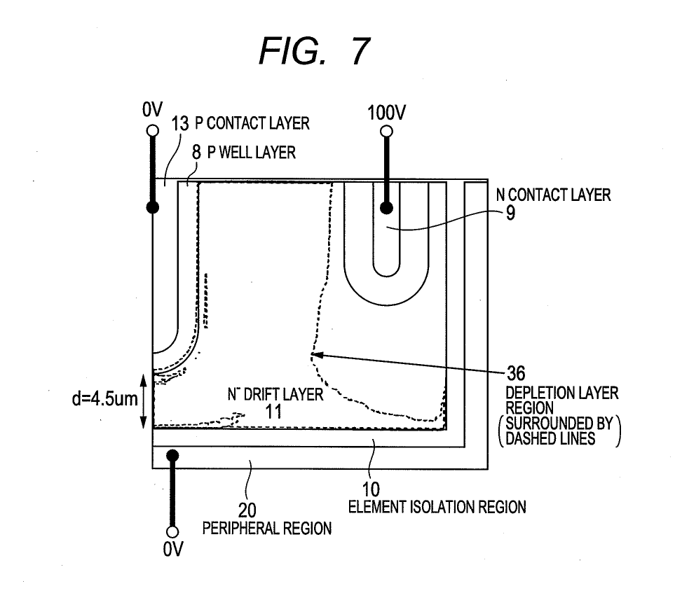

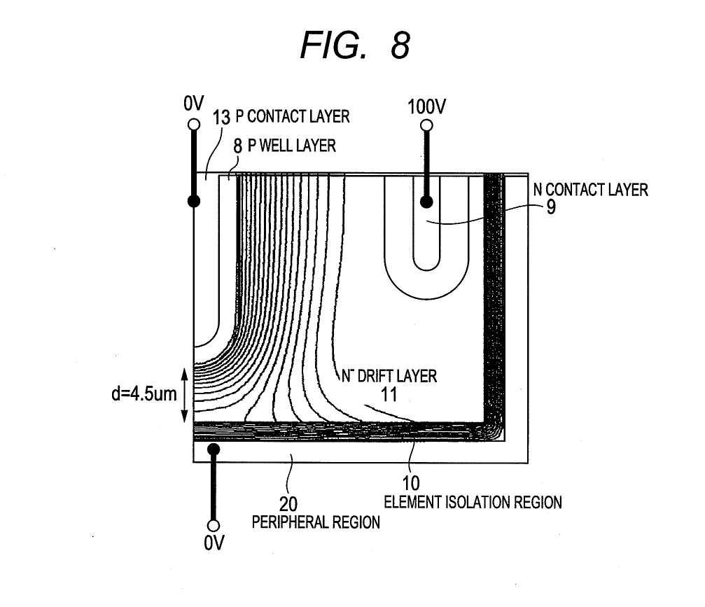

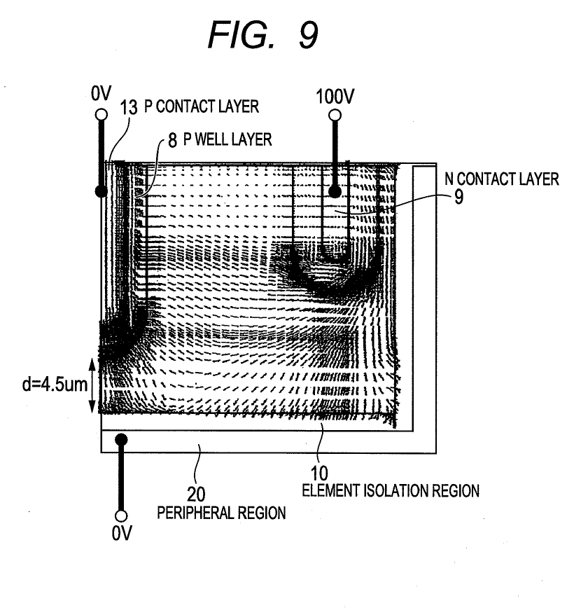

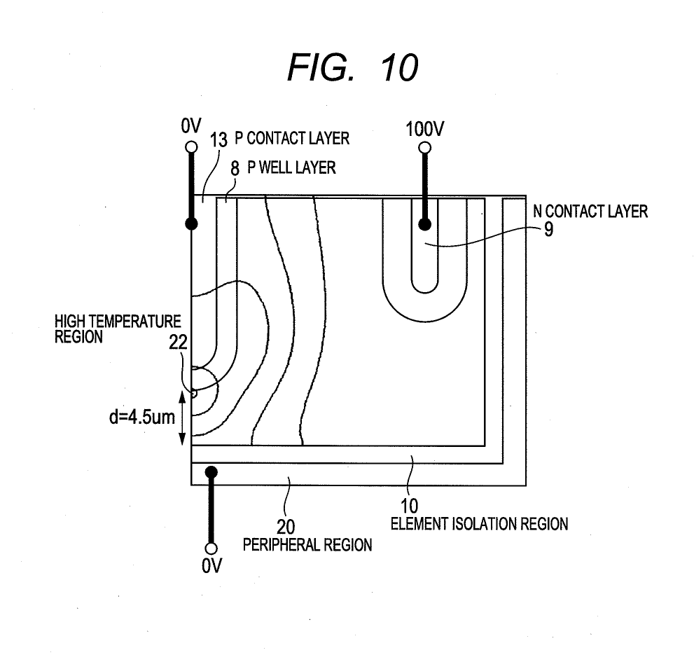

Concerning the high-voltage diode shown in FIGS. 2A to 2C with distance d assumed, in the present case, to be 4.5 μm, FIGS. 7 to 10 show a depletion layer region (FIG. 7), equipotential lines (FIG. 8), flow of holes (FIG. 9), and isothermal lines (FIG. 10) calculated for a state with reverse recovery taking place. Other conditions are the same as those shown in FIGS. 3 to 6.

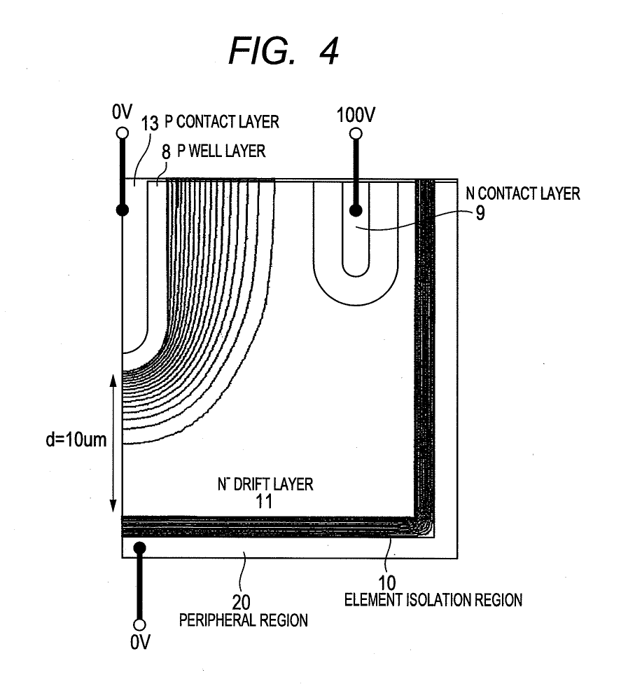

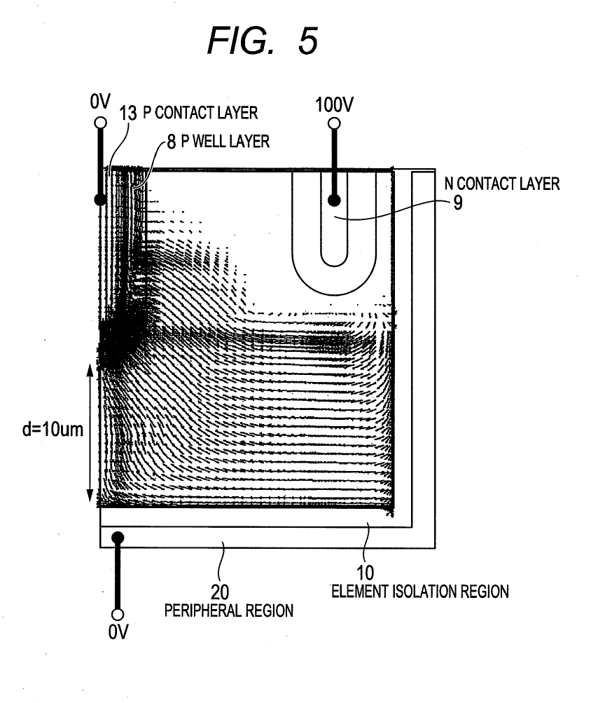

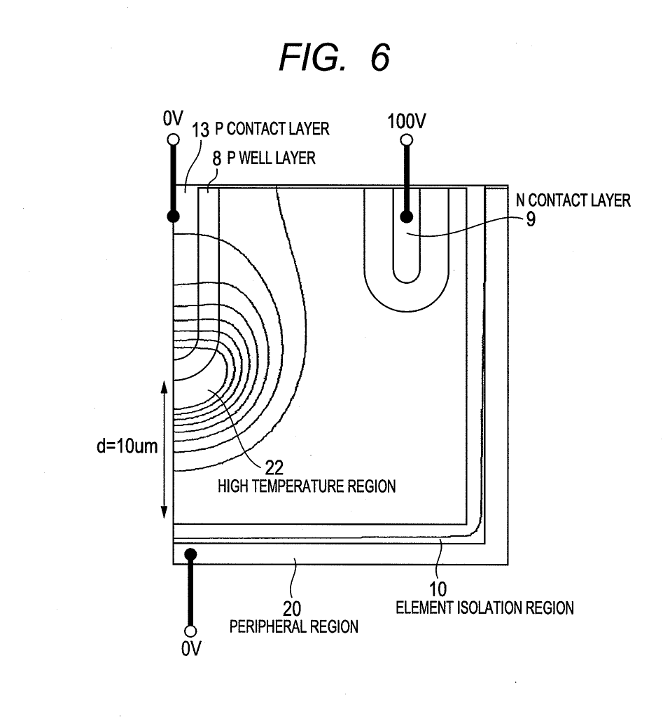

As shown in FIG. 9, holes flow toward a longitudinal end of the p well layer 8, but the flow is reduced compared with the example shown in FIG. 5 with a larger distance d. As shown in FIG. 7, the depletion layer extends from between the p well layer 8 and n⁻ drift layer 11 into the n⁻ drift layer, and the portion between the longitudinal end of the p well layer 8 and the element isolation region 10 of the n⁻ drift layer is depleted. Therefore, as shown in FIG. 8, the potential gradient from the longitudinal end of the p well layer 8 toward the element isolation region 10 is gentler than in the corresponding part shown in FIG. 4. This is considered to indicate that the electric field strength is reduced in the case shown in FIG. 8. Furthermore, as shown in FIG. 10, the temperature rise at the longitudinal end of the anode region is reduced compared with that shown in FIG. 6. This indicates that the longitudinal end of the anode region breaks down less easily and that the diode has enhanced reverse recovery capability. Thus, a diode structure has been realized in which the hole current concentration at a longitudinal end of a diffusion region included in an anode region is reduced and reverse recovery capability is enhanced.

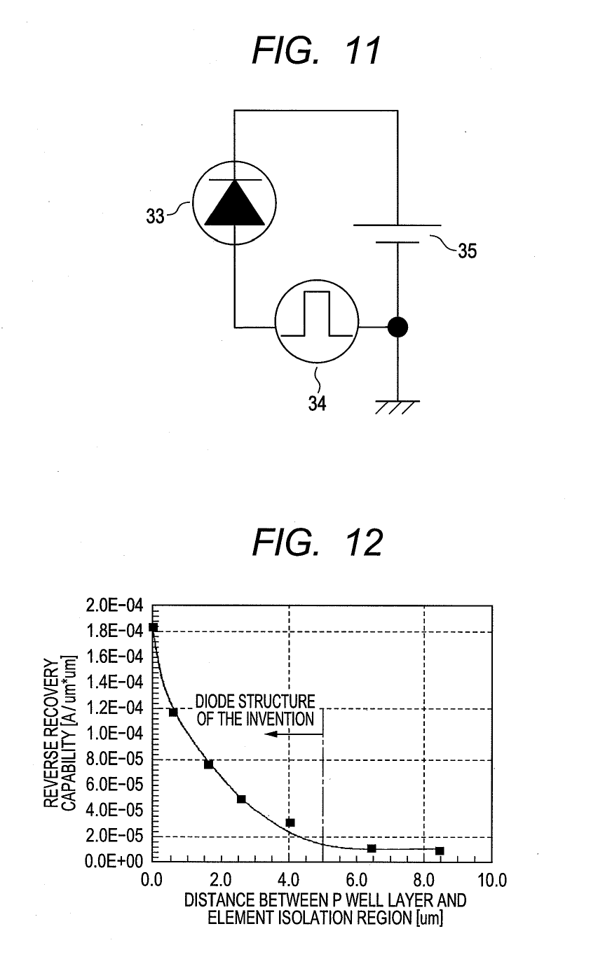

FIG. 12 shows measurements of reverse recovery capability measured using a circuit shown in FIG. 11. The measurement was performed using the distance between the p well layer and the element isolation region of a diode 33 as a parameter (the distance between the p well layer in the anode region and the n contact layer in the cathode region was 13.6 μm). In the measurement, with a voltage of 150 V applied in a reverse direction by a DC power supply 35, a 200-ns pulse voltage was applied in a forward direction by a transmission line pulse (TLP) tester 34, the direction of voltage application was shifted from forward to backward, and the maximum value of forward current measured immediately before breakdown of the diode was taken as reverse recovery capability.

As shown in FIG. 12, where distance d is 5 μm or larger, the reverse recovery capability is approximately constant and, as distance d is reduced to be shorter than 5 μm, the reverse recovery capability exponentially increases. This tendency is observed even when distance f between the longitudinal end of the n contact layer in the cathode region and the element isolation region formed to surround the diode is changed and also even when the distance between the anode region and the cathode region is changed. Thus, to enhance the reverse recovery capability of a diode, the depletion layer formed, when a maximum rated reverse voltage V_{R} is applied, near the p well layer in the anode region is required to extend so far as to contact the element isolation region and, in the case of a device as shown in FIGS. 2A to 2C, its reverse recovery capability is entirely dependent on distance d.

### Second Embodiment

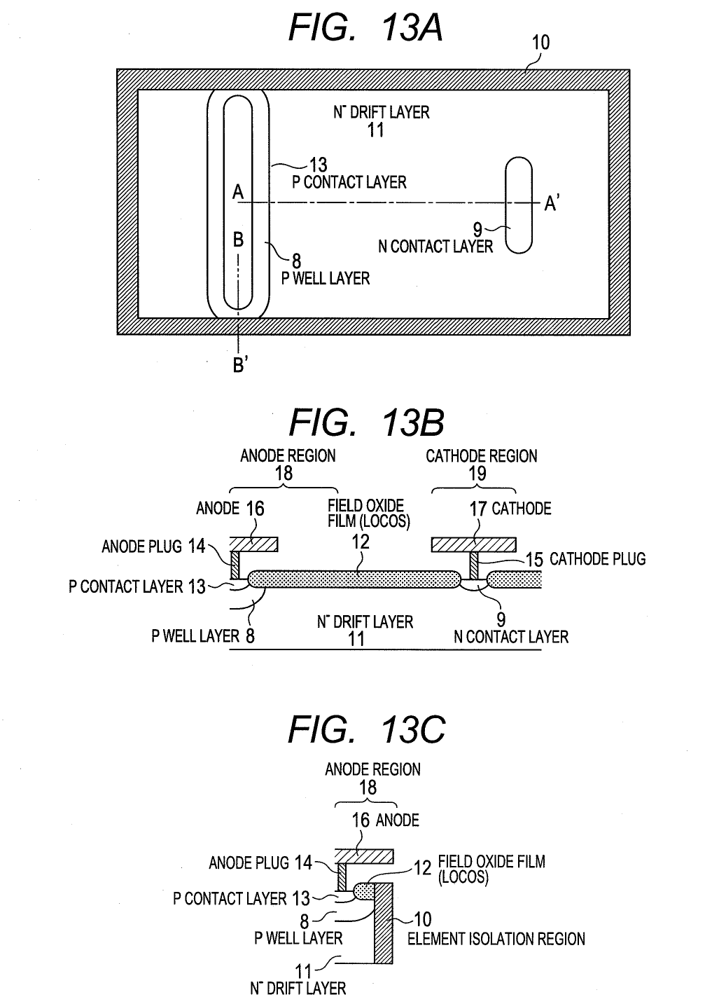

FIGS. 13A to 13C show a high-voltage diode according to a second embodiment of the present invention. In the second embodiment, the p well layer 8 in the anode region and the element isolation region 10 are in contact with each other as shown in FIG. 13A.

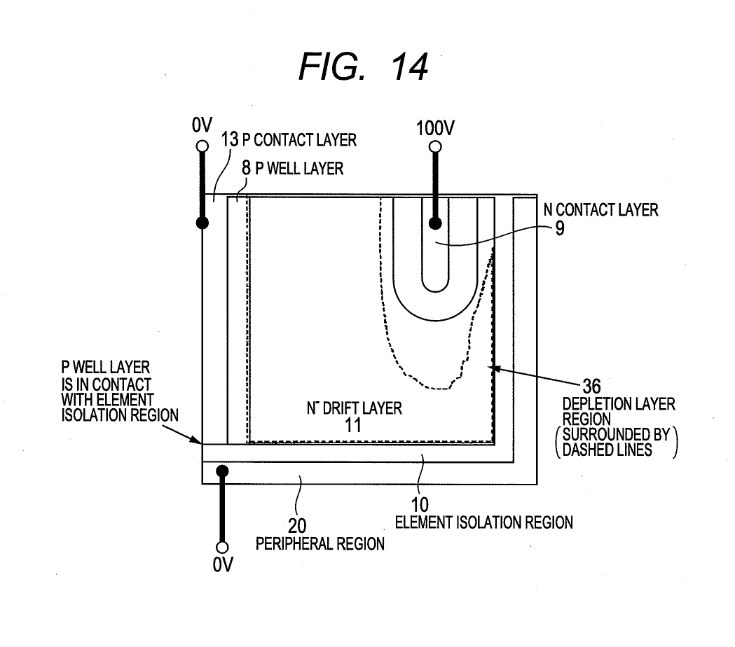

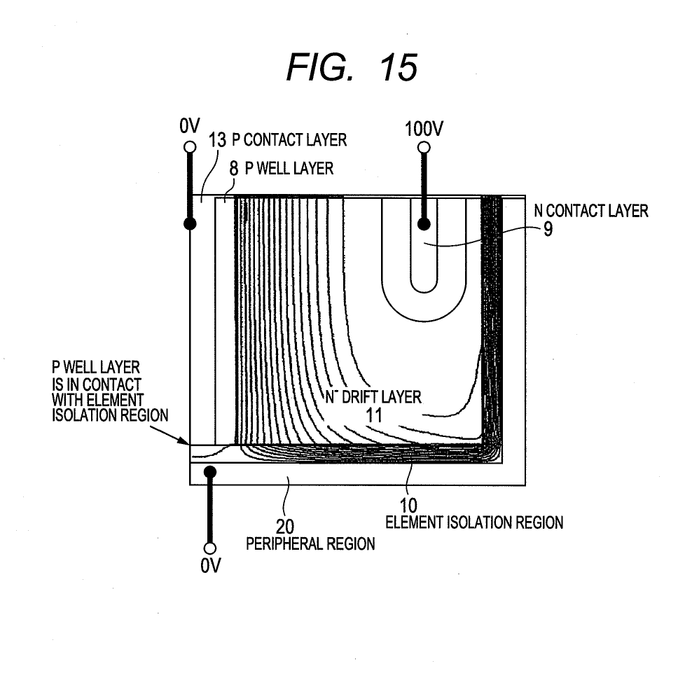

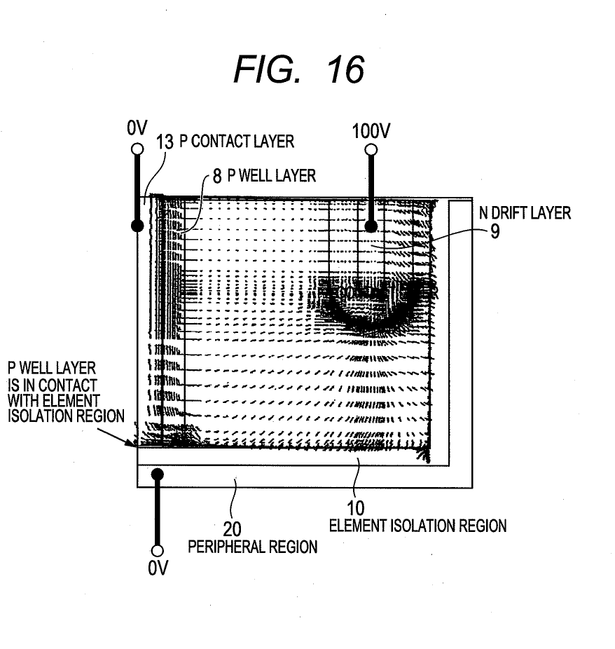

Concerning the high-voltage diode shown in FIGS. 13A to 13C, FIGS. 14 to 17 show a depletion layer region (FIG. 14), equipotential lines (FIG. 15), flow of holes (FIG. 16), and isothermal lines (FIG. 17) calculated for a state with reverse recovery taking place. Other conditions are the same as those shown in FIGS. 3 to 6.

As shown in FIG. 16, holes flow toward a longitudinal end of the p well layer 8, but comparing FIG. 16 with FIGS. 5 and 9 makes it known that the amount of holes flowing toward the longitudinal end of the p well layer 8 is reduced relative to that in the first embodiment. Also, as shown in FIG. 14, the depletion layer extends from between the p well layer 8 and the n⁻ drift layer 11 into the n⁻ drift layer 11 more extensively than in the first embodiment. Therefore, as shown in FIG. 15, the potential gradient from the longitudinal end of the p well layer 8 toward the element isolation region 10 is gentler than in the first embodiment, and the electric field strength is reduced compared with the first embodiment. Thus, the hole current concentration at the longitudinal end of the anode region is reduced. Furthermore, as shown in FIG. 17, the temperature rise at the longitudinal end of the anode region is reduced compared with those shown in FIGS. 6 and 10. This indicates that the diode does not easily break down and that its reverse recovery capability is further enhanced.

### Third Embodiment

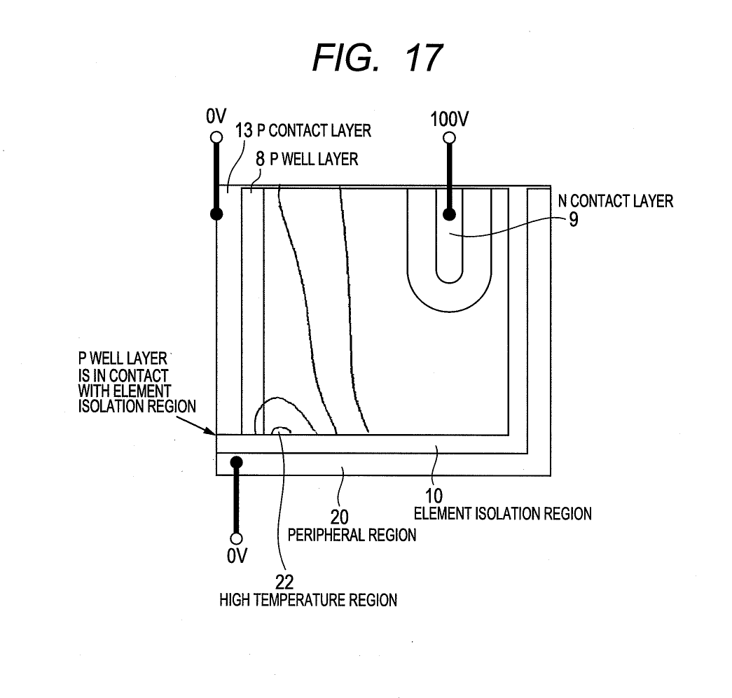

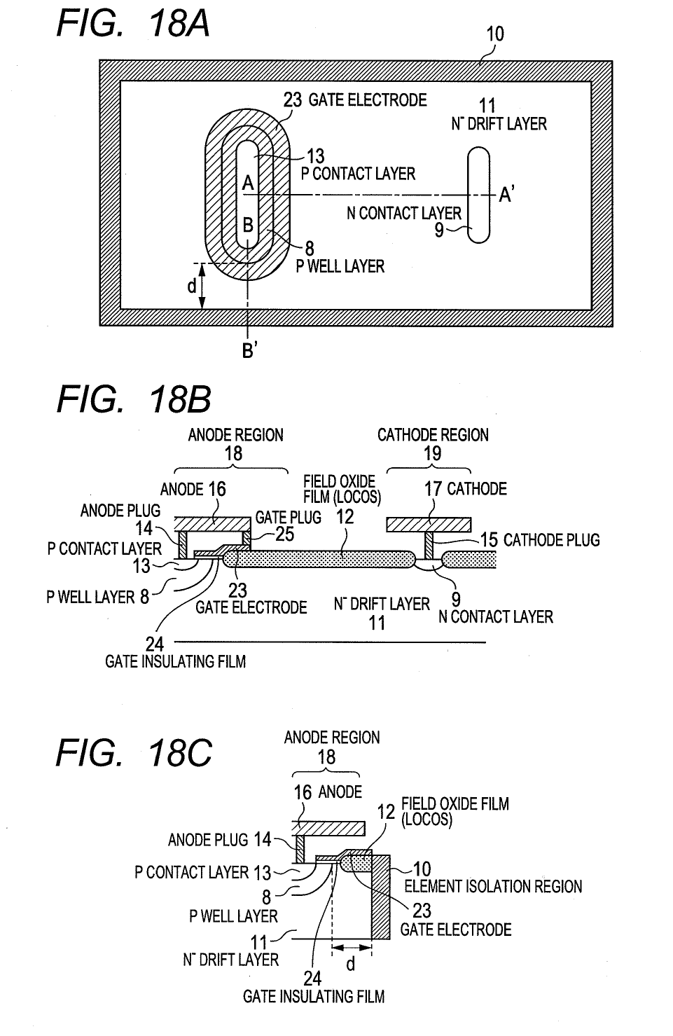

FIGS. 18A to 18C show a high-voltage diode according to a third embodiment of the present invention. FIG. 18A is a plan view; FIG. 18B is a sectional view (A-A′); and FIG. 18C is another sectional view (B-B′). As shown in FIG. 18B, an anode region 18 and a cathode region 19 are formed over a support substrate having an n⁻ drift layer 11. In the anode region 18, a p well layer 8 is selectively formed on the n⁻ drift layer 11, a p contact layer 13 is formed on the surface of the p well layer 8, and an anode 16 is conductively connected to the p contact layer 13 via an anode plug 14. A gate electrode 23 is formed on the surface of the p well layer 8 via a gate insulating film 24. The gate insulating film 24 is provided to cover an upper portion of a p-n junction formed by the n⁻ drift layer 11 and p well layer 8. The gate electrode 23 ranges over the gate insulating film 24 and a field oxide film 12. The gate electrode 23 is connected to the anode 16 via a gate plug 25. In the cathode region 19, an n contact layer 9 is selectively formed on the surface of the n⁻ drift layer 11 and a cathode 17 is conductively connected to the n contact layer 9 via a cathode plug 15. The n⁻ drift layer 11 exists between the p well layer 8 and the n contact layer 9. As shown in FIG. 18A, the anode region 18 and the cathode region 19 are formed to oppose each other. Furthermore, the entire element region is surrounded, for isolation, by an element isolation region 10 filled with insulation film. Distance d between a longitudinal end of the p well layer 8 in the anode region and the element isolation region 10 surrounding the diode does not exceed 5 μm. Also, distance d does not exceed a distance over which a depletion layer formed, when a maximum rated reverse voltage V_{R} is applied, near the p well layer in the anode region extends. Namely, like in the first embodiment, the depletion layer formed when a maximum rated reverse voltage V_{R} is applied contacts the element isolation region 10.

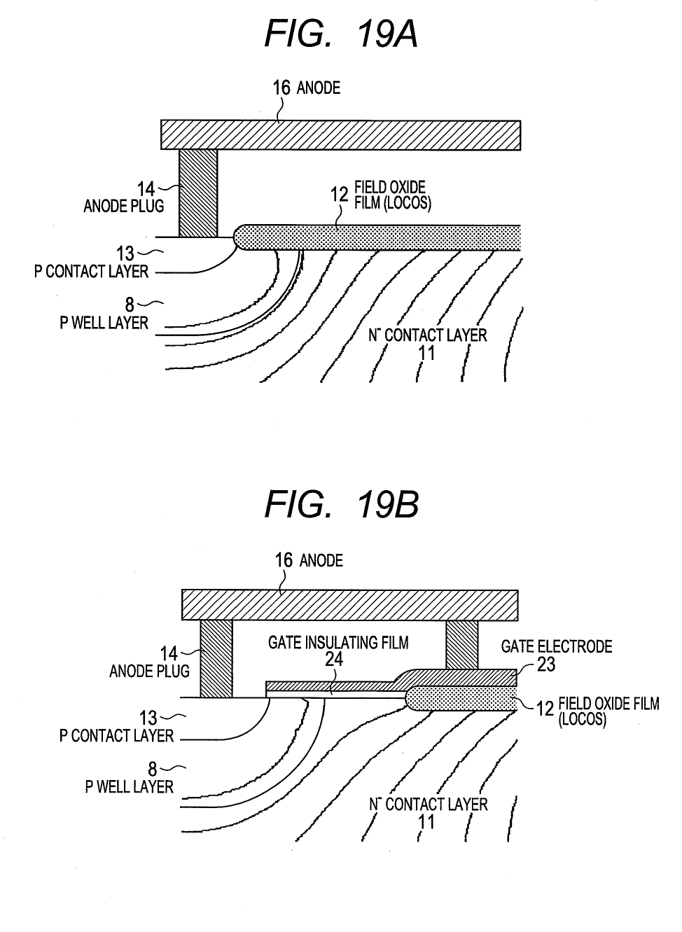

FIGS. 19A and 19B show equipotential lines drawn for the high-voltage diodes (for a portion near the anode region of each diode) according to the first and the third embodiments of the present invention, respectively, based on calculations made for a state with reverse recovery taking place. For the calculations on each diode, the n⁻ drift layer 11 was formed by injecting phosphorus ions, at a dose of 7.5E11 cm⁻² and an energy of 2.5 MeV, into a p-type semiconductor substrate doped with boron at a dose of 3.0E14 cm⁻²; the p well layer 8 was formed by injecting boron ions at a doze of 4.4E13 cm⁻² and an energy of 30 keV; the p contact layer 13 in the anode region 18 was formed by injecting boron ions at a dose of 5E15 cm⁻² and an energy of 40 keV; and the n contact layer 9 in the cathode region was formed by injecting arsenic ions at a dose of 4E15 cm⁻² and an energy of 69 keV. The p well layer 8 and the n contact layer 9 were arranged to be 12 μm apart. To observe reverse recovery, with the anode and peripheral electrodes kept at 0 V, a voltage of −3 V was applied to the cathode causing a forward current to flow, and the cathode voltage was raised to 100 V in 100 ns.

Comparing FIG. 19A and FIG. 19B makes it known that the equipotential lines around the boundary between the p well layer 8 and the n⁻ drift layer 11 are less dense in FIG. 19B than in FIG. 19A. This is because of an electric field relaxation effect of the gate electrode 23. Hence, in the present embodiment, the hole current concentration during reverse recovery is reduced, and the reverse recovery capability of the diode is further enhanced.

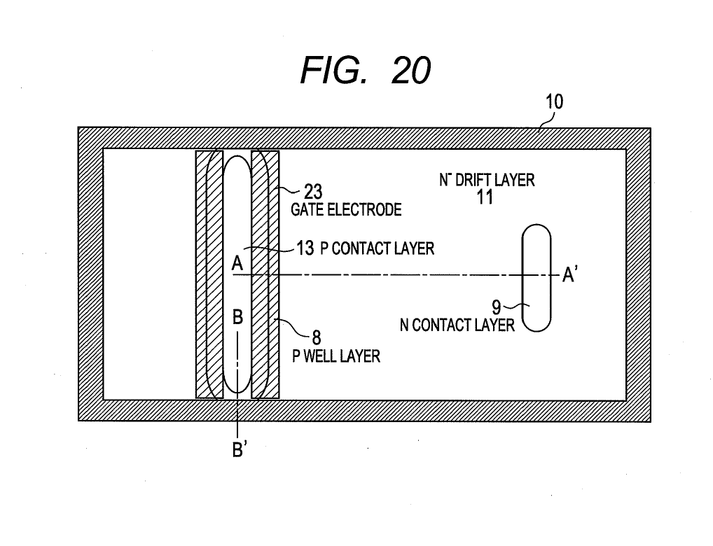

FIG. 20 is a plan view showing an example modification of the third embodiment. In this modification, as in the second embodiment, the p well layer 8 in the anode region is in contact with the element isolation region 10. Sectional views taken along lines A-A′ and B-B′ in FIG. 20 are the same as the sectional views shown in FIG. 18B and FIG. 13C, respectively. In this modified structure, the potential gradient, formed during reverse recovery, at the longitudinal end of the p well layer 8 is gentler and the hole current concentration is further reduced, so that the reverse recovery capability of the diode is further enhanced.

### Fourth Embodiment

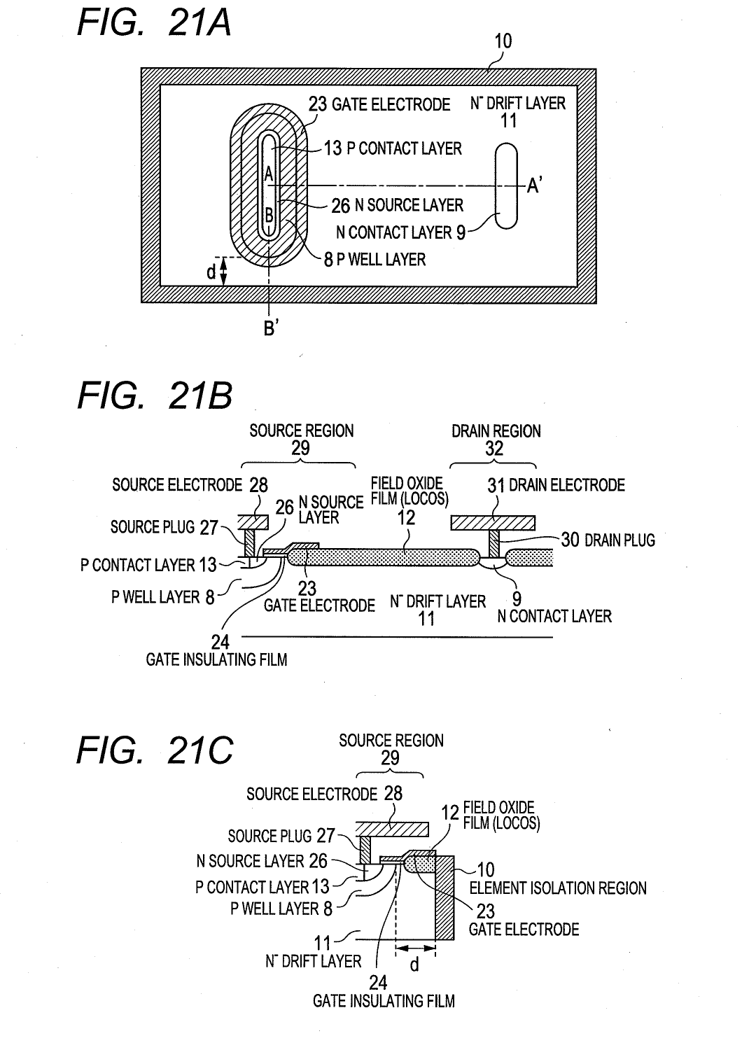

FIGS. 21A to 21C show a high-voltage N-channel metal oxide semiconductor (NMOS) according to a fourth embodiment of the present invention. FIG. 21A is a plan view; FIG. 21B is a sectional view (A-A′); and FIG. 21C is another sectional view (B-B′). As shown in FIG. 21B, a source region 29 and a drain region 32 are formed over a support substrate having an n⁻ drift layer 11. In the source region 29, a p well layer 8 is selectively formed on the n⁻ drift layer 11, an n source layer 26 and a p contact layer 13 are formed on the surface of the p well layer 8, and a source electrode 28 is conductively connected to the n source layer 26 and the p contact layer 13 via a source plug 27. A gate electrode 23 is formed on the surface of the p well layer 8 via a gate insulating film 24. In the drain region 32, an n contact layer 9 is selectively formed on the n⁻ drift layer 11 and a drain electrode 31 is conductively connected to the n contact layer 9 via a drain plug 30. The n⁻ drift layer 11 exists between the p well layer 8 and the n contact layer 9.

As shown in FIG. 21A, the source region 29 and the drain region 32 are arranged to oppose each other. Furthermore, the entire element region is surrounded, for isolation, by an element isolation region 10 filled with insulation film. Distance d between a longitudinal end of the p well layer 8 in the source region 29 and the element isolation region 10 surrounding the NMOS does not exceed 5 μm. Also, distance d does not exceed a distance over which a depletion layer formed, when a maximum rated voltage V_{OFF} for the high-voltage NMOS in an off state is applied, near the p well layer 8 in the source region 29 extends. Namely, like in the first embodiment, the depletion layer formed when a maximum rated voltage V_{OFF} is applied contacts the element isolation region 10. Thus, for reasons similar to those described concerning the third embodiment, the high-voltage NMOS shown in FIGS. 21A to 21C has enhanced reverse recovery capability.

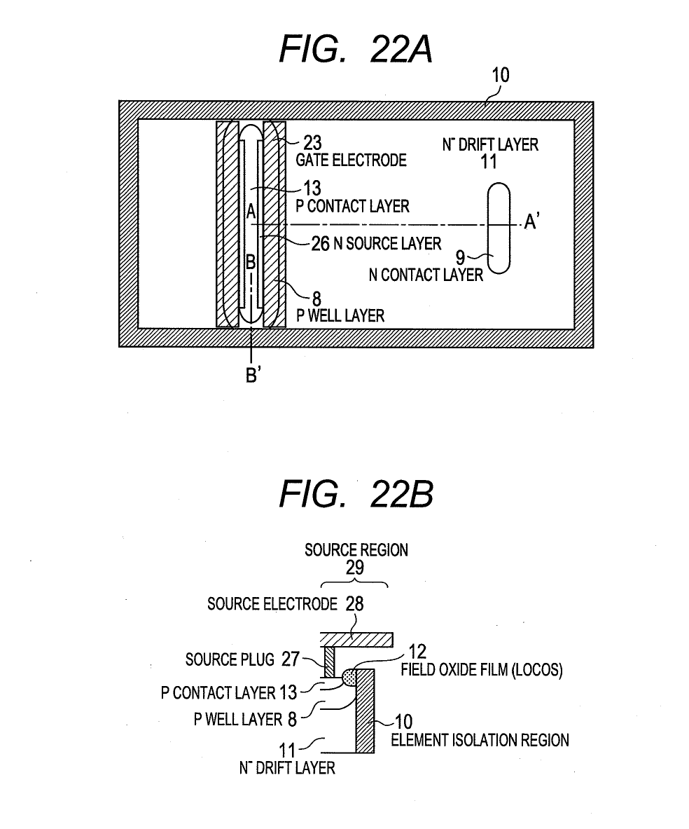

FIGS. 22A and 22B are a plan view and a sectional view (B-B′), respectively, showing an example modification of the fourth embodiment. In this modification, as in the second embodiment, the p well layer 8 in the source region 29 is in contact with the element isolation region 10. A sectional view taken along line A-A′ in FIG. 22A is the same as the sectional view shown in FIG. 21B. In this modified structure, the potential gradient, formed during reverse recovery of a parasitic diode formed by the p well layer 8 and the n⁻ drift layer 11 in the source region 29, at a longitudinal end of the p well layer 8 in the source region 29 is gentler and the hole current concentration is further reduced, so that the reverse recovery capability of the NMOS is enhanced.

### Fifth Embodiment

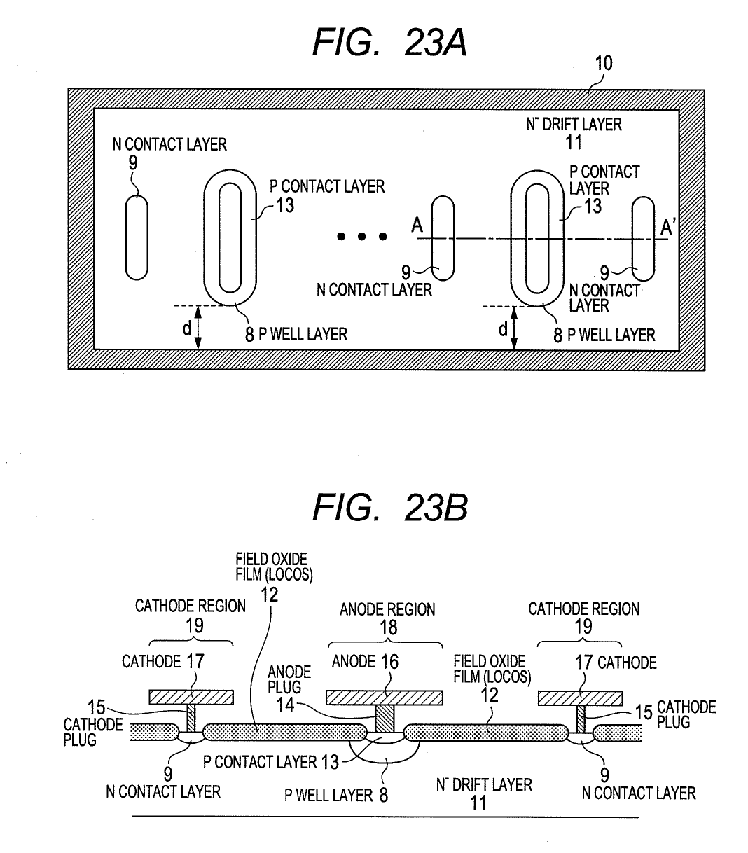

FIGS. 23A and 23B are a plan view and a sectional view (A-A′), respectively, showing a high-voltage diode according to a fifth embodiment of the present invention. The diode includes plural pairs of alternately arranged, equally spaced anode regions and cathode regions all enclosed in an element isolation region. Each of the plural anode regions has the same structure as that of the first embodiment.

In the diode including plural pairs of alternately arranged, equally spaced anode regions and cathode regions all enclosed in an element isolation region, each anode region may have the same structure as that of the second or the third embodiment.

Also, the high-voltage NMOS according to the fourth embodiment of the present invention may be structured similarly to the diode of the fifth embodiment. Namely, the NMOS may include plural pairs of alternately arranged, equally spaced source regions and drain regions all enclosed in an element isolation region with each of the plural source regions having the same structure as that of the fourth embodiment.

What is claimed is:

1. A diode comprising:
a semiconductor layer of a first conductivity type;
a first semiconductor region of a second conductivity type and a second semiconductor region both formed in the semiconductor layer, the second semiconductor region having a higher density than the semiconductor layer; and
an element isolation region electrically isolating the semiconductor layer from a peripheral region;
wherein the first semiconductor region and the second semiconductor region are each stripe-shaped and are arranged such that a long side of the first semiconductor region and a long side of the second semiconductor region oppose each other; and
wherein a distance between a longitudinal end of the first semiconductor region and the element isolation region is such that, when a maximum rated reverse voltage is applied, a depletion layer extending from the longitudinal end of the first semiconductor region at least contacts the element isolation region.

2. The diode according to claim 1, wherein the distance between the longitudinal end of the first semiconductor region and the element isolation region is 5 μm or shorter.

3. The diode according to claim 1, wherein the longitudinal end of the first semiconductor region is in contact with the element isolation region.

4. The diode according to claim 1, further comprising:
a field oxide film layer provided between the first semiconductor region and the second semiconductor region;
a gate insulating film provided over a p-n junction formed by the semiconductor layer and the first semiconductor region; and
a gate electrode formed over the gate insulating film and the field oxide film;
wherein the gate electrode and the second semiconductor region are electrically connected.

5. A transistor comprising:
a semiconductor layer of a first conductivity type;
a first semiconductor region of a second conductivity type and a second semiconductor region both formed in the semiconductor layer, the second semiconductor region having a higher density than the semiconductor layer;
a field oxide film layer provided between the first semiconductor region and the second semiconductor region;
a gate insulating film provided over a p-n junction formed by the semiconductor layer and the first semiconductor region; and
an element isolation region electrically isolating the semiconductor layer from a peripheral region;
wherein the first semiconductor region and the second semiconductor region are each stripe-shaped and are arranged such that a long side of the first semiconductor region and a long side of the second semiconductor region oppose each other; and
wherein a distance between a longitudinal end of the first semiconductor region and the element isolation region is such that, when a maximum rated reverse voltage for an off state is applied, a depletion layer extending from the longitudinal end of the first semiconductor region at least contacts the element isolation region.

6. The transistor according to claim 5, wherein the distance between the longitudinal end of the first semiconductor region and the element isolation region is 5 μm or shorter.

7. The transistor according to claim 5, wherein the longitudinal end of the first semiconductor region is in contact with the element isolation region.
